(19) United States
(12) Patent Application Publication
(10) Pub. No.: US 2025/0087574 A1
(43) Pub. Date: Mar. 13, 2025

(54) WIRING BOARD, SEMICONDUCTOR DEVICE, AND METHOD OF MANUFACTURING WIRING BOARD

(71) Applicant: SHINKO ELECTRIC INDUSTRIES CO., LTD., Nagano-shi (JP)

(72) Inventor: Keiichi Hirabayashi, Nagano (JP)

(21) Appl. No.: 18/828,389

(22) Filed: Sep. 9, 2024

(30) Foreign Application Priority Data
Sep. 13, 2023 (JP) 2023-148740

(51) Int. Cl. H01L 23/498; H01L 23/00

(52) U.S. Cl. CPC H01L 23/49838; H01L 23/49822; H01L 24/16; H01L 24/32; H01L 24/73; H01L 2224/16227; H01L 2224/32225; H01L 2224/73204

(57) ABSTRACT

A wiring board includes a core board, a first interconnect structure, a second interconnect structure, and a through-hole. The core board includes an interconnect layer that is formed on an upper surface and a lower surface of a substrate. The first interconnect structure includes an interconnect layer and an insulating layer that are layered on the core board. The second interconnect structure includes an interconnect layer and an insulating layer that are layered on the core board. The through-hole penetrates the insulating layer of the second interconnect structure and the substrate of the core board to a pad that is contained in the interconnect layer of the core board or penetrates the insulating layer of the second interconnect structure, the substrate of the core board, and the insulating layer of the first interconnect structure to a pad that is contained in the interconnect layer of the first interconnect structure.

### CROSS-REFERENCE TO RELATED APPLICATION

This application is based upon and claims the benefit of priority of the prior Japanese Patent Application No. 2023-148740, filed on Sep. 13, 2023, the entire contents of which are incorporated herein by reference.

### FIELD

The embodiment discussed herein is related to a wiring board, a semiconductor device, and a method of manufacturing a wiring board.

### BACKGROUND

For example, conventional wiring boards on each of which a semiconductor chip is mounted include a wiring board having a multilayer interconnect structure that is formed by, for example, a semi-additive method. Specifically, an interconnect layer is formed on an insulating layer by electrolytic plating and electroless plating and an insulating layer that covers the interconnect layer is further formed. As described above, repeating layering an insulating layer and an interconnect layer forms a wiring board having a multilayer interconnect structure.

In such a wiring board, vias penetrating an insulating layer are formed as required and pads contained in adjacent interconnect layers are connected electrically. Accordingly, interconnects are formed by the pads of the respective interconnect layers and the vias in the wiring board having the multilayer interconnect structure.

Patent Literature 1: Japanese Laid-open Patent Publication No. 2022-165329

The wiring board described above, however, has a problem in that, because the more the number of insulating layers and interconnect layers increases, the more the number of portions where a via connects pads contained in adjacent interconnect layers increases, reliability in connection of the interconnects formed in the wiring board lowers. Specifically, for example, a stress caused by a thermal shock, or the like, tends to occur at the interface between the pad of each interconnection layer and the via and therefore, when the number of portions of connection of pads via a via increases, separation at the interface between a pad in each interconnect layer and a via tends to occur. As a result, the pads in the respective interconnect layers and the vias lower reliability in connection of interconnects formed in the wiring board.

There is also a problem that an increase in the number of layers of insulating layers and interconnect layers increases the number of pads and vias and thus transmission properties lower. Specifically, the structure of a portion of connection between a pad and a via is discontinuous as a conductor and impedance inconsistency in the portion of discontinuity increases. A parasitic capacitance between the pads and a ground pattern also increases. This lowers the transmission properties in interconnects formed in the wiring board.

### SUMMARY

According to an aspect of an embodiment, a wiring board includes a core board including an interconnect layer that is formed on an upper surface and a lower surface of a substrate; a first interconnect structure that includes an interconnect layer and an insulating layer that are layered on an upper surface of the core board; a second interconnect structure that includes an interconnect layer and an insulating layer that are layered on a lower surface of the core board; and a through-hole that penetrates the insulating layer of the second interconnect structure and the substrate of the core board to a pad that is contained in the interconnect layer of the core board or that penetrates the insulating layer of the second interconnect structure, the substrate of the core board, and the insulating layer of the first interconnect structure to a pad that is contained in the interconnect layer of the first interconnect structure.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to an embodiment;

FIG. 2 is a flowchart illustrating a method of manufacturing a semiconductor device according to the embodiment;

FIG. 3 is a diagram illustrating a specific example of a core board forming process;

FIG. 4 is a diagram illustrating a specific example of a build-up process;

FIG. 5 is a diagram illustrating a specific example of a solder resist layer forming process;

FIG. 6 is a diagram illustrating a specific example of a terminal forming process;

FIG. 7 is a diagram illustrating a specific example of a through-hole forming process;

FIG. 8 is a diagram illustrating a specific example of a semiconductor chip mounting process;

FIG. 9 is a diagram illustrating a specific example of a mounting process;

FIG. 10 is a diagram illustrating a configuration of a wiring board according to Modification 1 of the embodiment;

FIG. 11 is a diagram illustrating an example of a configuration of a semiconductor device including the wiring board in FIG. 10;

FIG. 12 is a diagram illustrating a configuration of a wiring board according to Modification 2 of the embodiment; and

FIG. 13 is a diagram illustrating an example of a configuration of a semiconductor device including the wiring board in FIG. 12.

### DESCRIPTION OF EMBODIMENT

An embodiment of a wiring board, a semiconductor device, and a method of manufacturing a wiring board disclosed herein will be described in detail below with reference to the accompanying drawings. Note that the embodiments do not limit the disclosed technique.

### Embodiment

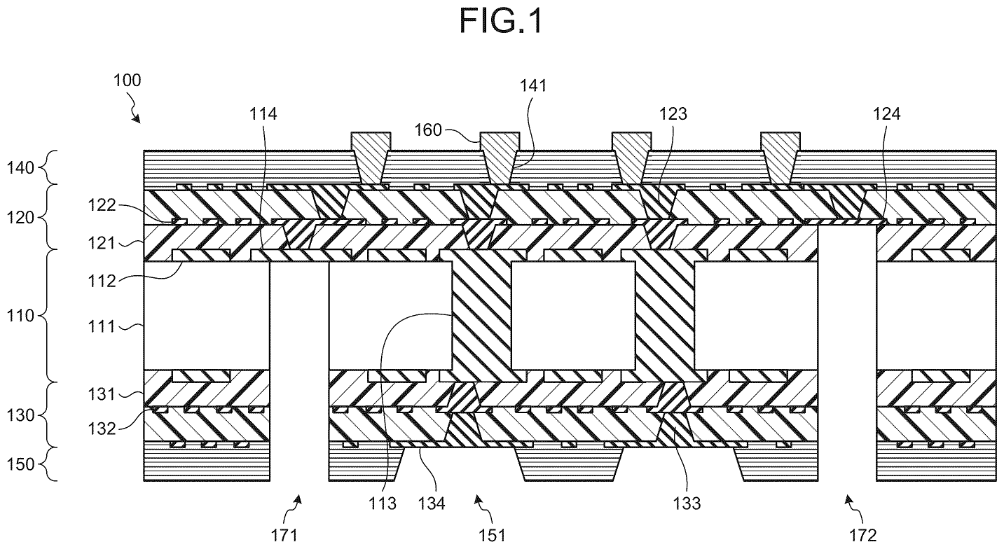

FIG. 1 is a diagram illustrating a configuration of a wiring board 100 according to the embodiment. FIG. 1 schematically illustrates a cross-section of the wiring board 100. The wiring board 100 illustrated in FIG. 1 is usable as a board of a semiconductor device on which a semiconductor chip is mounted.

The wiring board 100 is a layered structure and includes a core board 110, interconnect structures 120 and 130 and solder resist layers 140 and 150. As illustrated in FIG. 1, the solder resist layer 150 will be described as the lowest layer and the solder resist layer 140 will be described as the highest layer below; however, the wiring board 100, for example, may be used upside down and may be used in any posture.

The core board 110 is obtained by forming interconnect layers 112 by plating on upper and lower surfaces of a substrate 111 that is a platy insulator. A via 113 connects the interconnect layers 112 on the upper and lower surfaces as required.

On the interconnect layer 112 on the upper surface, a pad 114 serving as a contact terminal that makes contact with an electrode pin on a side of a mount board, such as a mother board, when the wiring board 100 is mounted on the mount board is formed.

The interconnect structure 120 is formed on an upper surface of the core board 110 and is obtained by layering a layer including an insulating layer 121 that is insulating and an interconnect layer 122 that is conducting. According to FIG. 1, the two layers are layered in the interconnect structure 120; however, the number of layers layered may be one or three or larger. The insulating layer 121 is formed, for example, using insulating resin, such as epoxy resin or polyimide resin. The interconnect layer 122 is formed, for example, using metal, such as copper. A via 123 connects the interconnect layers 122.

On the interconnect layer 122 that is a given layer, a pad 124 serving as a contact terminal that makes contact with an electrode pin on the side of the mount board, such as a mother board, when the wiring board 100 is mounted on the mount board is formed.

The interconnect structure 130 is formed on a lower surface of the core board 110 and is obtained by layering a layer including an insulating layer 131 that is insulating and an interconnect layer 132 that is conducting. According to FIG. 1, the two layers are layered in the interconnect structure 130; however, the number of layers layered may be one or three or larger. The insulating layer 131 is formed, for example, using insulating resin, such as epoxy resin or polyimide resin. The interconnect layer 132 is formed, for example, using metal, such as copper. A via 133 connects the interconnect layers 132.

On the interconnect layer 132 that is the lowest layer, a pad 134 serving as a contact terminal that makes contact with an electrode pin on the side of a mount board, such as a mother board, when the wiring board 100 is mounted on the mount board is formed.

The solder resist layer 140 is a layer that covers the interconnect layer 122 on a surface of the interconnect structure 120 and that protects the interconnects. The solder resist layer 140 is a layer, for example, made of insulating photosensitive resin, such as acrylic resin and polyimide resin, and is one of insulating layers. Note that the solder resist layer 140 may be formed, for example, using insulating non-photosensitive resin, such as epoxy resin. The solder resist layer 140 and the interconnect structure 120 are an example of a first interconnect structure.

The side of the solder resist layer 140 of the wiring board 100 is a surface on which electronic parts, such as a semiconductor chip, is mounted. In a position in which a semiconductor chip is mounted, an opening 141 is formed in the solder resist layer 140. When the solder resist layer 140 is formed using photosensitive resin, it is possible to form the opening 141 by exposure and development. When the solder resist layer 140 is formed using non-photosensitive resin, it is possible to form the opening 141 by laser processing. In the opening 141, a connection terminal 160 that connects the interconnect layer 122 of the interconnect structure 120 and an electrode of the semiconductor chip is formed.

The solder resist layer 150 is a layer that covers the interconnect layer 132 on the surface of the interconnect structure 130 and that protects the interconnect. The solder resist layer 150 is a layer, for example, made of insulating photosensitive resin, such as acrylic resin and polyimide resin, and is one of insulating layers. Note that the solder resist layer 150 may be formed, for example, using insulating non-photosensitive resin, such as epoxy resin. The solder resist layer 150 and the interconnect structure 130 are an example of a second interconnect structure.

The side of the solder resist layer 150 of the wiring board 100 is a surface that is mounted on a mount board. In a position of the mounting on the mount board, an opening 151 is formed in the solder resist layer 150 and the pad 134 serving as a contact terminal that makes contact with the electrode pin on the side of the mount board is exposed from the opening 141.

A through-hole 171 is formed in the solder resist layer 150, the insulating layer 131 of the interconnect structure 130, and the substrate 111 of the core board 110. The through-hole 171 penetrates to the pad 114 contained in the interconnect layer 112 on an upper surface of the core board 110 and the pad 114 is exposed on a bottom plane of the through-hole 171. A through-hole 172 is formed in the solder resist layer 150, the insulating layer 131 of the interconnect structure 130, the substrate 111 of the core board 110, and the insulating layer 121 of the interconnect structure 120. The through-hole 172 penetrates to the pad 124 contained in the interconnect layer 122 of the interconnect structure 120 that is the given layer and the pad 124 is exposed on a bottom plane of the through-hole 172.

As described above, in the embodiment, because the through-hole 171 allowing the pad 114 serving as a terminal of contact with an electrode pin on the side of the mount board to be exposed is formed in the interconnect structure 130 and the core board 110, another pad and another via are not arranged under the pad 114. Furthermore, because the through-hole 172 allowing the pad 124 serving as a terminal of contact with an electrode pin on the side of the mount board is formed in the solder resist layer 150, the interconnect structure 130, the core board 110, and the interconnect structure 120, another pad and another via are not arranged under the pad 124. Accordingly, it is possible to reduce portions of connection between pads via a via in the wiring board 100. As a result, it is possible to inhibit occurrence of separation at the interface between pads and a via that form an interconnect in the wiring board 100 and reduce discontinuous conducting structure and thus it is possible to increase reliability in connection and transmission properties in the interconnects in the wiring board 100.

In the embodiment, the pads 114 and 124 are signal pads for transmitting signals for which a transfer rate is higher than that for signals that are transmitted to the pad 134 contained in the interconnect layer 132 that is the lowest layer in the interconnect structure 130. Accordingly, it is possible to realize an increase in the rate of transmission of signals that are transmitted using the pads 114 and 124.

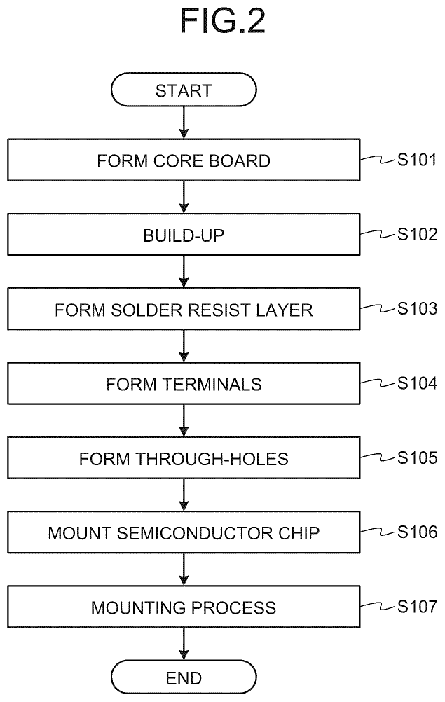

A method of manufacturing a semiconductor device including the wiring board 100 configured as described above will be descried next with reference to FIG. 2, taking an example specifically. FIG. 2 is a flowchart illustrating the method of manufacturing a semiconductor device according to the embodiment.

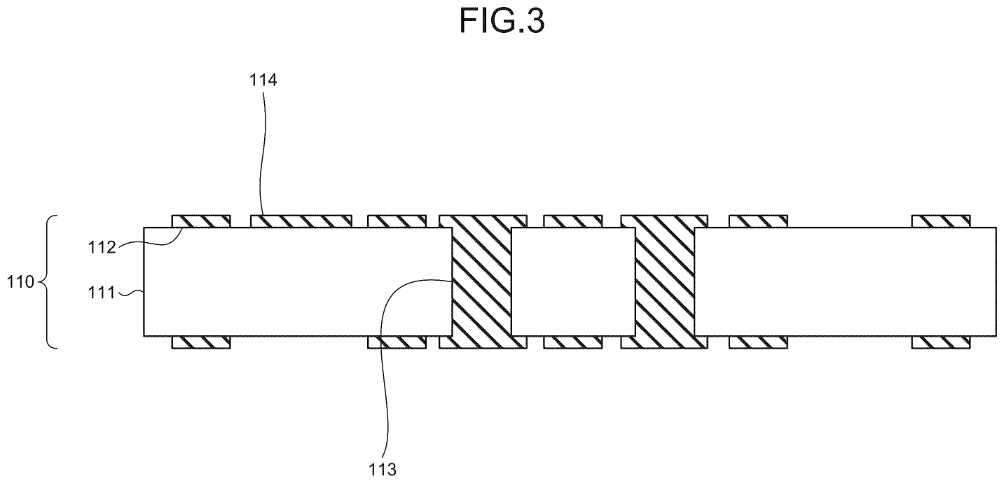

First of all, the core board 110 serving as a support member of the wiring board 100 is formed (step S101). Specifically, for example, as illustrated in FIG. 3, the via 113 that penetrates the substrate 111 that is a platy insulator is formed in the substrate 111 and the interconnect layers 112 made of metal, such as copper, are formed on the upper surface and the lower surface of the substrate 111 using copper foil or copper plating. FIG. 3 is a diagram illustrating a specific example of a core board forming process.

The via 113 that is formed, for example, of plating of metal, such as copper, connects the interconnect layers 112 on the upper and lower surfaces of the substrate 111 as required. It is possible to use, as the substrate 111, for example, one obtained by impregnating a reinforcing member, such as glass woven fabric, with insulating resin, such as epoxy resin. In addition to glass woven fabric, glass non-woven fabric, aramid woven fabric, or aramid non-woven fabric is usable as the reinforcing member. In addition to epoxy resin, polyimide resin or cyanate resin is usable as the insulating resin. The pad 114 is formed in a due position where the through-hole 171 is to be formed in the interconnect layer 112 on the upper surface of the substrate 111. Note that the interconnect layer 112 is not arranged in a due position where the through-hole 171 is to be formed on the lower surface of the substrate 111. The interconnect layer 112 is not arranged in a due position where the through-hole 172 is to be formed on the upper surface and the lower surface of the substrate 111.

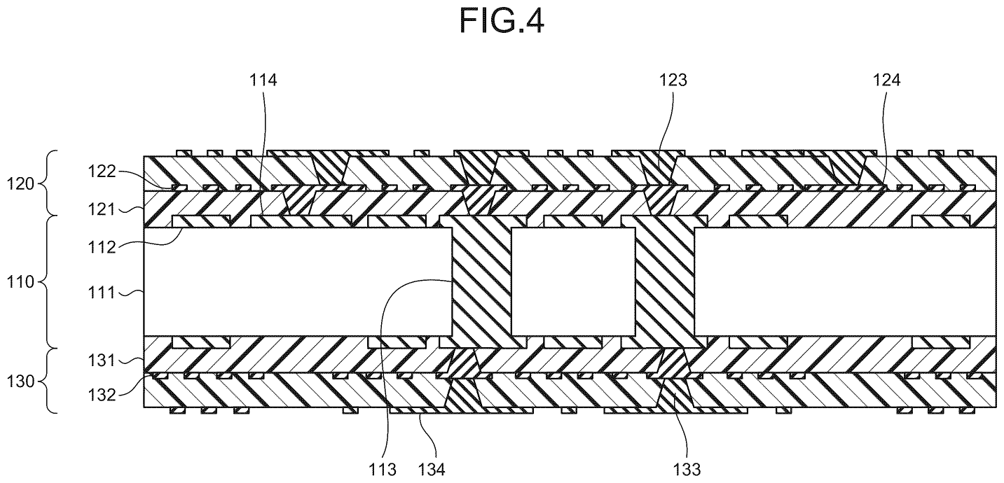

The interconnect structures 120 and 130 are formed by a build-up technique on an upper surface and a lower surface of the core board 110 (step S102). Specifically, for example, as illustrated in FIG. 4, the layer including the insulating layer 121 and the interconnect layer 122 is layered on the upper surface of the core board 110 and thereby the interconnect structure 120 is formed. The layer including the insulating layer 131 and the interconnect layer 132 is layered on the lower surface of the core board 110 and thereby the interconnect structure 130 is formed. FIG. 4 is a diagram illustrating a specific example of a build-up process. The insulating layers 121 and 131 are formed, for example, using insulating resin, such as epoxy resin or polyimide resin. The interconnect layers 122 and 132 are formed, for example, by plating using metal, such as copper.

The via 123 that is formed, for example, of plating of metal, such as copper, connects the interconnect layer 112 and the interconnect layer 122 that are on the upper surface of the core board 110 as required. The via 133 that is formed, for example, of plating of metal, such as copper, connects the interconnect layer 112 and the interconnect layer 132 that are on the lower surface of the core board 110 as required. A plurality of the insulating layers 121 and a plurality of the interconnect layers 122 may be layered on the upper surface of the core board 110 and a plurality of the insulating layers 131 and a plurality of the interconnect layers 132 may be layered on the lower surface of the core board 110. On the interconnect layer 122 that is the given layer, the pad 124 is formed in a due position where the through-hole 172 is to be formed. On the interconnect layer 132 that is the lowest layer, the pad 134 is formed. Note that, in the interconnect structure 130, the interconnect layer 132 is not arranged in a due position where the through-hole 171 is to be formed. In the interconnect structures 120 and 130, the interconnect layers 122 and 132 are not arranged in a due positions where the through-hole 172 is to be formed.

After the interconnect structures 120 and 130 are formed, the interconnect layers 122 and 132 of the interconnect structures 120 and 130 that are the outermost layers are covered with the solder resist layers 140 and 150 (step S103). For example, the interconnect layer 122 of the interconnect structure 120 that is the highest layer is covered with the solder resist layer 140 and the interconnect layer 132 of the interconnect structure 130 that is the lowest layer is covered with the solder resist layer 150.

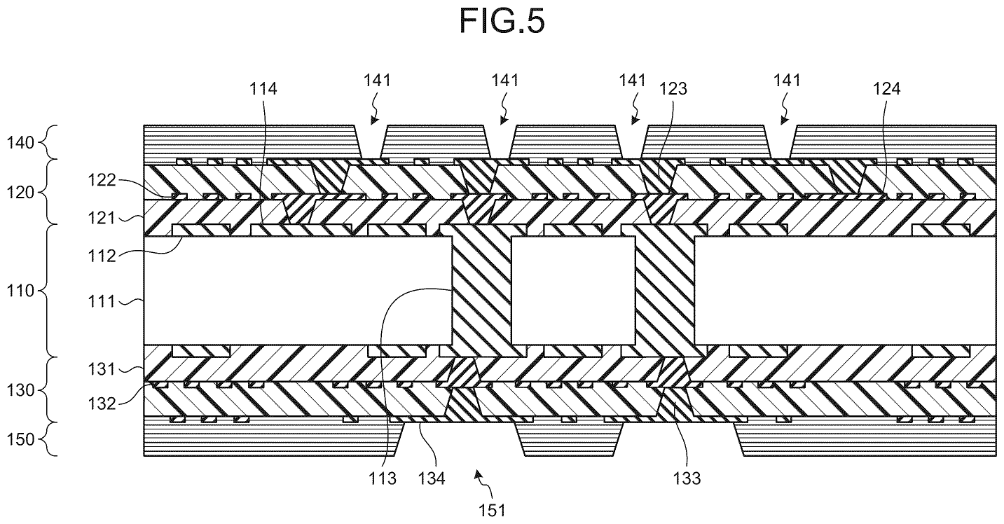

For example, as illustrated in FIG. 5, the openings 141 are formed in the positions in which the terminals of connection with the semiconductor chip are to be provided in the solder resist layer 140 on the side where the semiconductor chip is mounted. The interconnect layer 122 of the interconnect structure 120 that is the highest layer is exposed at the bottom surface of the opening 141. On the other hand, the openings 151 are formed in the solder resist layer 150 on the side of mounting on the mount board. The pad 134 contained in the interconnect layer 132 of the interconnect structure 130 that is the lowest layer is exposed at a bottom plane of the opening 151. FIG. 5 is a diagram illustrating a specific example of a solder resist layer forming process.

When photosensitive resin is used as the solder resist layers 140 and 150, it is possible to form the openings 141 and 151 by exposure and development. When non-photosensitive resin is used as the solder resist layers 140 and 150, it is possible to form the openings 141 and 151 by laser processing.

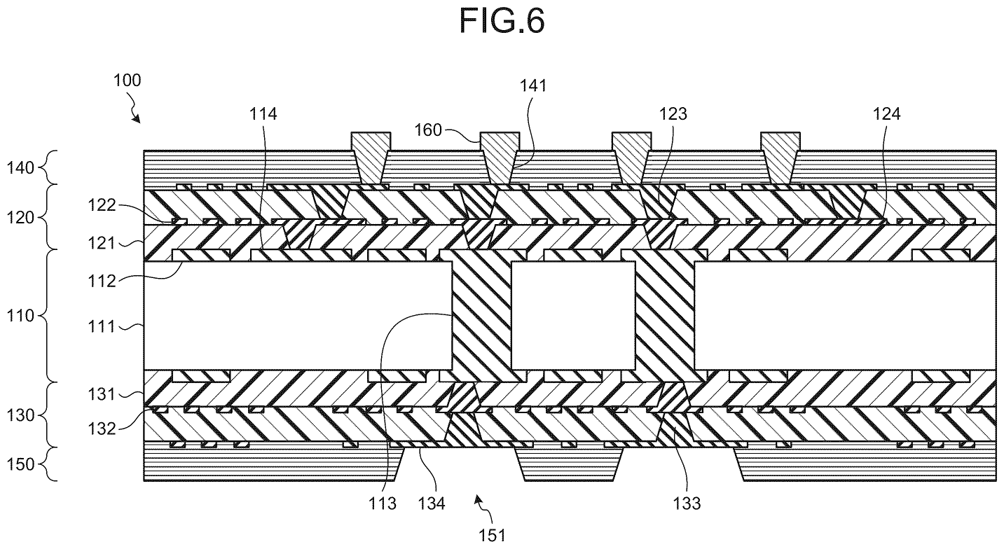

In the opening 141 of the resist solder resist layers 140 and 150, a connection terminal for connecting the semiconductor chip is formed (step S104). In other words, for example, as illustrated in FIG. 6, the connection terminal 160 is formed, for example, by copper plating in the opening 141. FIG. 6 is a diagram illustrating a specific example of a terminal forming process.

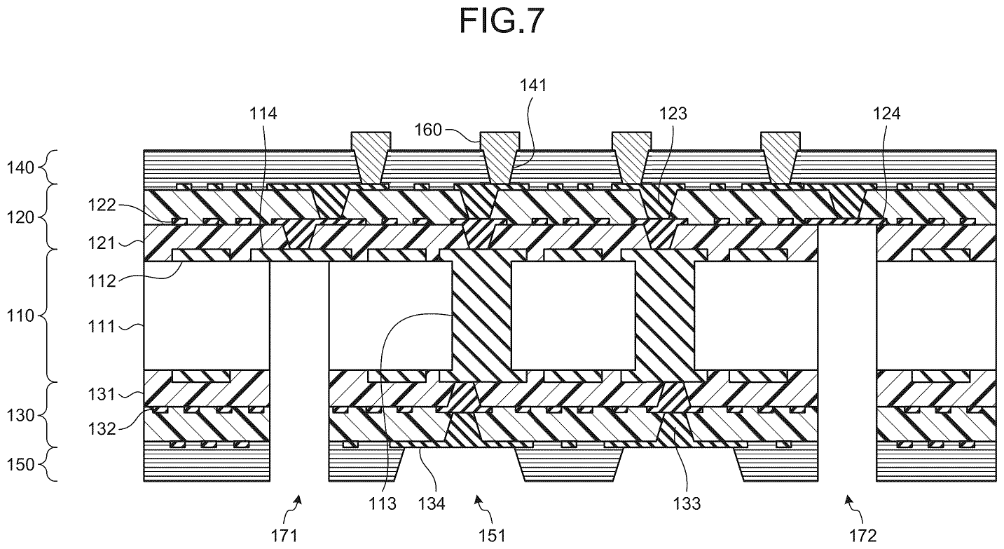

Subsequently, the through-hole 171 is formed in the solder resist layer 150, the interconnect structure 130, and the core board 110 and the through-hole 172 is formed in the solder resist layer 150, the interconnect structure 130, the core board 110, and the interconnect structure 120 (step S105). Specifically, for example, as illustrated in FIG. 7, the solder resist layer 150, the insulating layer 131 of the interconnect structure 130, and the substrate 111 of the core board 110 are cut to the pad 114 contained in the interconnect layer 112 on the upper surface of the core board 110 and thus the through-hole 171 is formed. The solder resist layer 150, the insulating layer 131 of the interconnect structure 130, the substrate 111 of the core board 11, and the insulating layer 121 of the interconnect structure 120 is cut to the pad 124 contained in the interconnect layer 122 of the interconnect structure 120 that is the given layer and thus the through-hole 172 is formed. FIG. 7 is a diagram illustrating a specific example of a through-hole forming process. The through-holes 171 and 172 are formed, for example, by drilling. For drilling, a contact sensor capable of sensing electric contact with metal is used and timing at which the tip of the drill makes contact with the pads 114 and 124 is sensed, and drilling is stopped.

The through-holes 171 and 172 are formed and accordingly the wiring board 100 completes. A semiconductor chip is mounted on the side of the solder resist layer 140 of the wiring board 100 (step S106) and the connection terminals 160 and the electrodes of the semiconductor chip are connected.

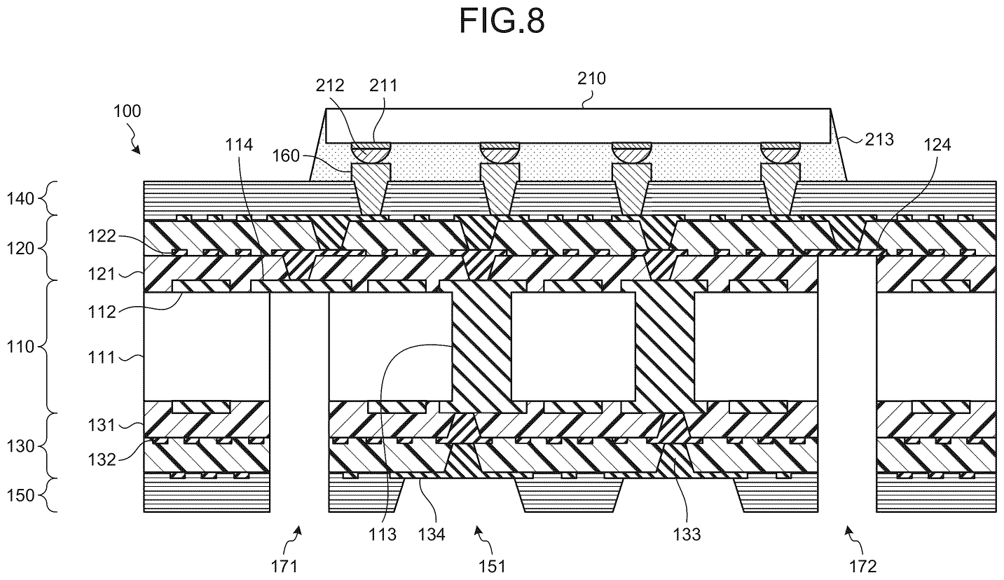

Specifically, for example, as illustrated in FIG. 8, a semiconductor chip 210 is mounted above the connection terminals 160. FIG. 8 is a diagram illustrating a specific example of a semiconductor chip mounting process. The semiconductor chip 210 is mounted on the wiring board 100 by joining electrodes 211 to the connection terminals 160 with, for example, solder 212, or the like, and sealing the joints each between the electrode 211 and the connection terminal 160 with under fill resin 213.

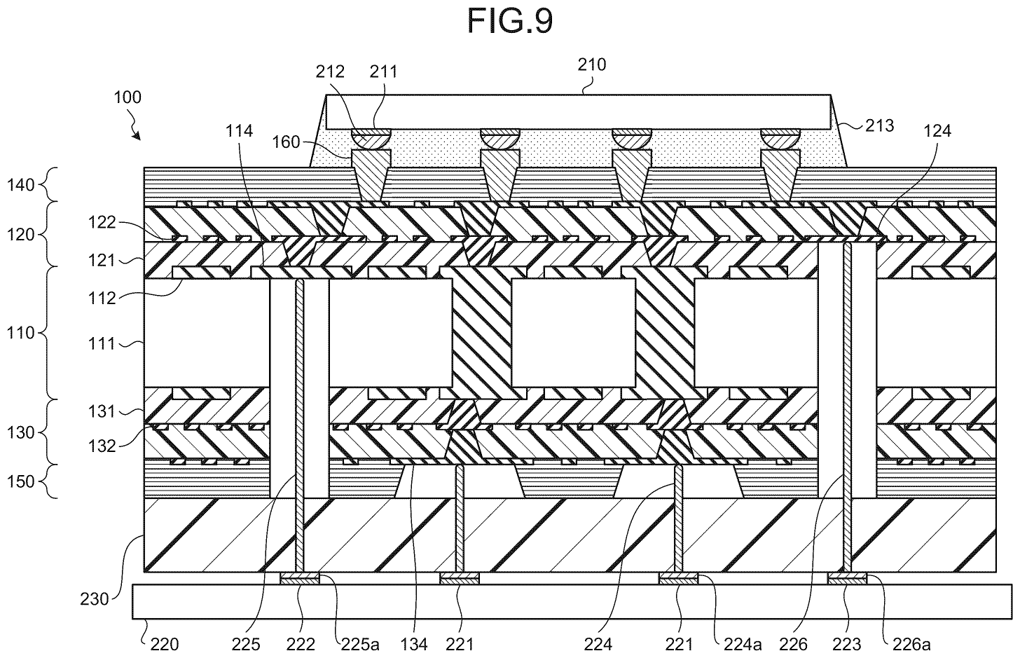

For example, as illustrated in FIG. 9, the wiring board 100 with the semiconductor chip 210 being mounted thereon, for example, is mounted on a mount board 220, such as a mother board (step S107) and the semiconductor device completes. FIG. 9 is a diagram illustrating a specific example of the mounting process. Electrode pads 221 to 223 are formed on an upper surface of the mount board 220 and electrode pins 224 to 226 are connected to the upper surface of the mount board 220, for example, with solders 224a to 226a such that the electrode pins 224 to 226 stand up. The electrode pins 224 to 226 serve as connection terminals when the wiring board 100 is mounted on the mount board 220. The electrode pins 224 to 226 are held by a holder 230, for example, made of insulating resin.

The electrode pin 224 is inserted into the opening 151 of the solder resist layer 150 and makes contact with the pad 134 that is exposed from the opening 151.

An electrode pin 225 is inserted into the through-hole 171 of the wiring board 100 and makes contact with the pad 114 that is exposed from the through-hole 171. Accordingly, the pad 114 and the electrode pin 225 are connected electrically in a position closer to the semiconductor chip 210 than to the pad 134, which makes it possible to reduce parts of connection of pads via a via and reduce a discontinuous conductor structure between the semiconductor chip 210 and the mount board 220. As a result, it is possible to increase reliability in connection and transmission properties in the internal interconnects in the wiring board 100.

The electrode pin 226 is inserted into the through-hole 172 of the wiring board 100 and makes contact with the pad 124 that is exposed from the through-hole 172. Accordingly, the pad 124 and the electrode pin 226 are connected electrically in a position closer to the semiconductor chip 210 than to the pad 134, which makes it possible to reduce portions of connection of pads via a via and reduce discontinuous conductor structures between the semiconductor chip 210 and the mount board 220. As a result, it is possible to increase reliability in connection and transmission properties in the internal interconnects in the wiring board 100.

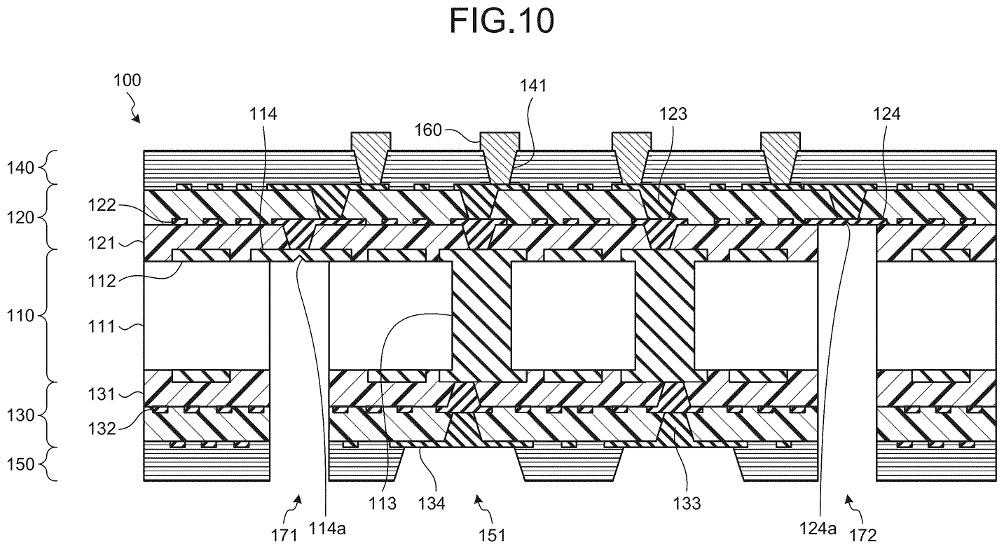

Various modifications of the embodiment will be described with reference to FIGS. 10 to 13. Note that, in the various modifications illustrated below, the same parts as those of the embodiment are denoted with the same reference numeral and thus redundant description will be sometimes omitted.

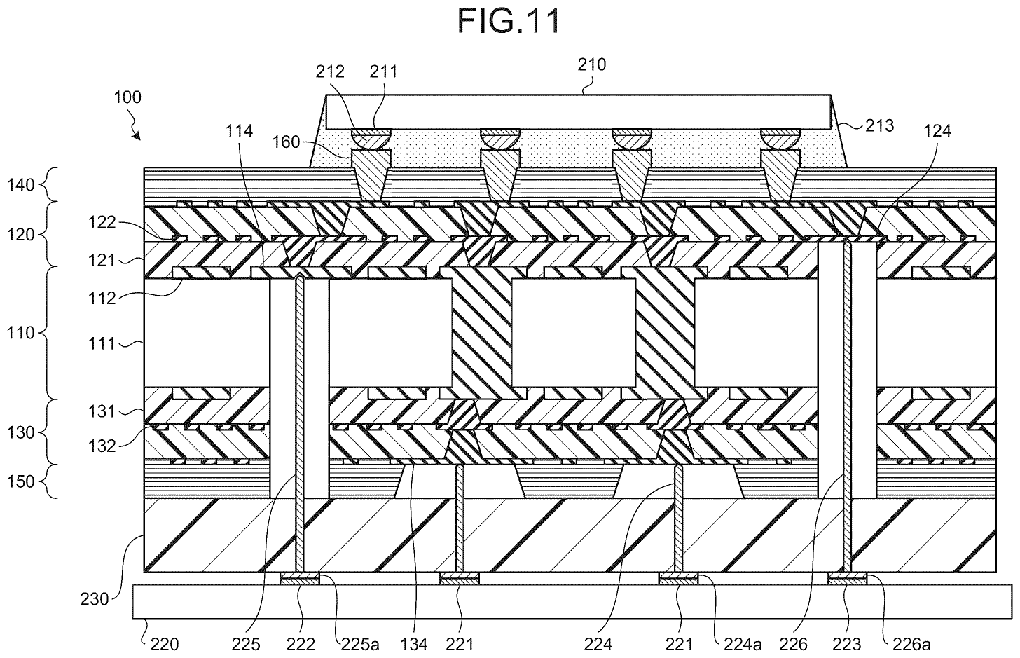

FIG. 10 is a diagram illustrating a configuration of the wiring board 100 according to Modification 1 of the embodiment. FIG. 11 is a diagram illustrating an example of a configuration of a semiconductor device including the wiring board 100 in FIG. 10. The wiring board 100 according to Modification 1 is different from the embodiment in that the pads 114 and 124 are provided with concaves.

Specifically, in Modification 1, the pad 114 of the wiring board 100 has a concave 114a on a surface that is exposed to a bottom plane of the through-hole 171. The electrode pin 225 of the mount board 220 is fitted in the concave 114a of the pad 114. This inhibits a positional shift between the pad 114 and the electrode pin 225, which makes it possible to increase reliability in connection between the wiring board 100 and the mount board 220.

In Modification 1, the concave 114a has a taper shape in which the width decreases as it separates from the plane where the pad 114 is exposed. This further inhibits a positional shift between the pad 114 and the electrode pin 225, which makes it possible to further increase reliability in connection between the wiring board 100 and the mount board 220.

In Modification 1, the pad 124 of the wiring board 100 includes a concave 124a on a surface that is exposed to a bottom plane of the through-hole 172. The electrode pin 226 of the mount board 220 is fitted in the concave 124a of the pad 124. This inhibits a positional shift between the pad 124 and the electrode pin 226, which makes it possible to increase reliability in connection between the wiring board 100 and the mount board 220.

In Modification 1, the concave 124a has a taper shape whose width decreases as it separates from the plane where the pad 124 is exposed. This further inhibits a positional shift between the pad 124 and the electrode pin 226, which makes it possible to further increase reliability in connection between the wiring board 100 and the mount board 220.

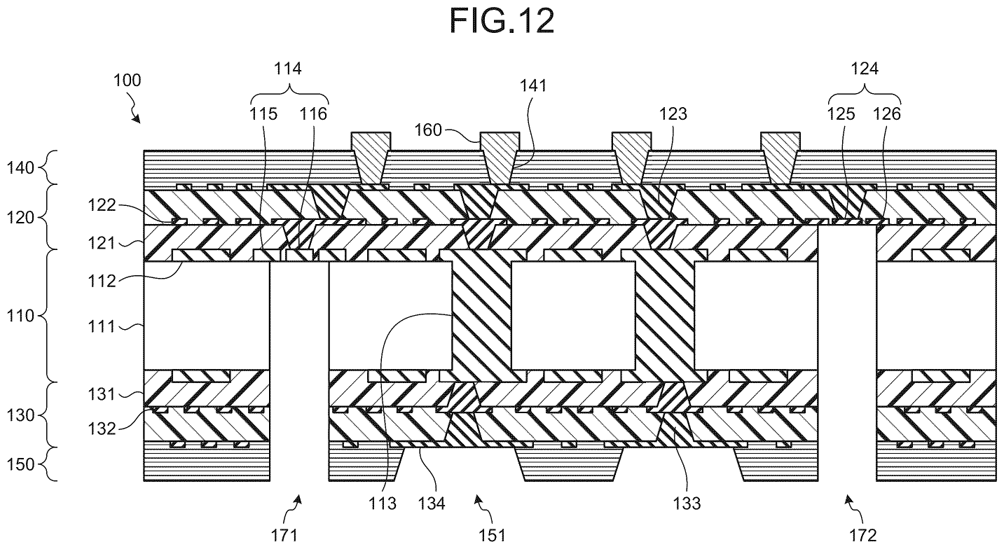

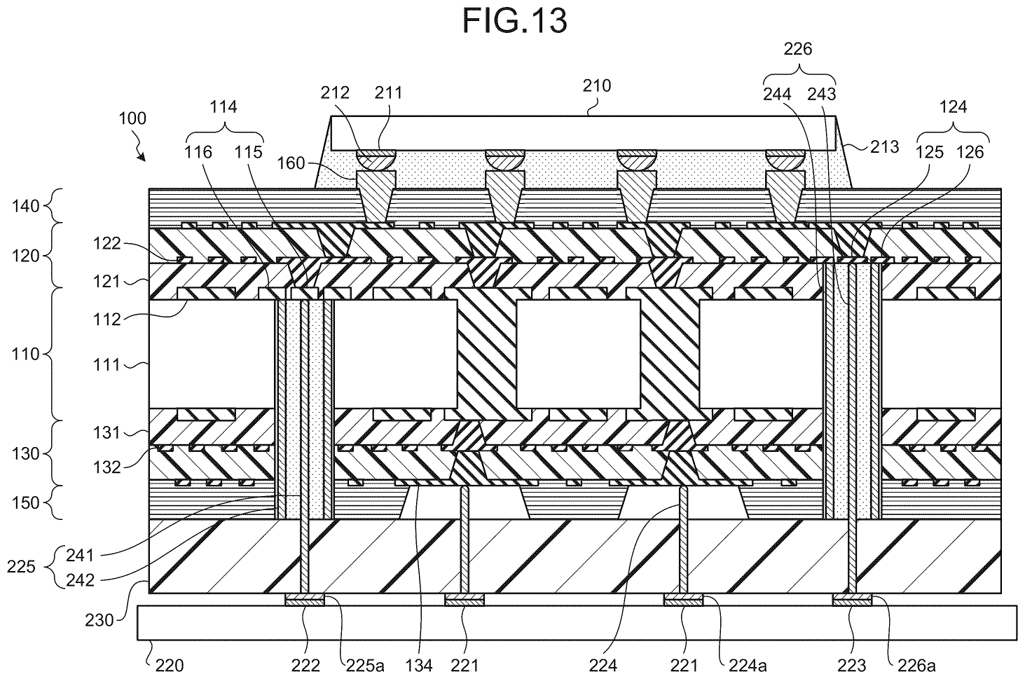

FIG. 12 is a diagram illustrating a configuration of the wiring board 100 according to Modification 2 of the embodiment. FIG. 13 is a diagram illustrating an example of a configuration of a semiconductor device that includes the wiring board 100 in FIG. 12. In the wiring board 100 according to Modification 2, the structure of the pads 114 and 124 is different from that of the embodiment. In the semiconductor device according to Modification 2, the structure of the electrode pins 225 and 226 is different from that of the embodiment.

Specifically, in Modification 2, the pad 114 of the wiring board 100 includes a signal pad 115 for signals and a ground pad 116 for grounding that is arranged around the signal pad 115. The ground pad 116 is set at a ground potential. On the other hand, the electrode pin 225 of the mount board 220 includes an internal conductor 241 for signals and an external conductor 242 that is arranged such that the external conductor 242 surrounds an outer circumference of the internal conductor 241. The external conductor 242 is set at a ground potential. The space between the internal conductor 241 and the external conductor 242 is filled with insulating resin. With the electrode pin 225 being inserted into the through-hole 171, the internal conductor 241 makes contact with the signal pad 115 and the external conductor 242 makes contact with the ground pad 116. Accordingly, the ground pad 116 and the external conductor 242 shut entry of noise in a transmission signal of the signal pad 115 and the internal conductor 241, which makes it is possible to increase transmission properties between the wiring board 100 and the mount board 220.

In Modification 2, the pad 124 of the wiring board 100 includes a signal pad 125 for signals and a ground pad 126 for grounding that is arranged around the signal pad 125. The ground pad 126 is set at a ground potential. On the other hand, the electrode pin 226 of the mount board 220 includes an internal conductor 243 for signals and an external conductor 244 that is arranged such that the external conductor 244 surrounds an outer circumference of the internal conductor 243. The external conductor 242 is set at a ground potential. The space between the internal conductor 243 and the external conductor 244 is filled with insulating resin. With the electrode pin 226 being inserted into the through-hole 172, the internal conductor 243 makes contact with the signal pad 125 and the external conductor 244 makes contact with the ground pad 126. Accordingly, the ground pad 126 and the external conductor 244 shut entry of noise in a transmission signal of the signal pad 125 and the internal conductor 243, which makes it is possible to increase transmission properties between the wiring board 100 and the mount board 220.

As described above, a wiring board (for example, the wiring board 100) according to the embodiment includes a core board (for example, the core board 110), a first interconnect structure (for example, the interconnect structure 120 and the solder resist layer 140), a second interconnect structure (for example, the interconnect structure 130 and the solder resist layer 150), and a through-hole (for example, the through-holes 171 and 172). The core board includes an interconnect layer (for example, the interconnect layer 112) that is formed on an upper surface and a lower surface of a substrate (for example, the substrate 111). The first interconnect structure includes an interconnect layer (for example, an interconnect layer 122) and an insulating layer (for example, the insulating layer 121 and the solder resist layer 140) that are layered on an upper surface of the core board. The second interconnect structure includes an interconnect layer (for example, the interconnect layer 132) and an insulating layer (for example, the insulating layer 131 and the solder resist layer 150) that are layered on a lower surface of the core board. The through-hole penetrates the insulating layer of the second interconnect structure and the substrate of the core board to a pad (for example, the pad 114) that is contained in the interconnect layer of the core board or penetrates the substrate of the core board and the insulating layer of the first interconnect structure to a pad (for example, the pad 124) contained in the interconnect layer of the first interconnect structure. This makes it possible to increase reliability in connection and transmission properties in interconnects in the wiring board.

According to a mode of a wiring board disclosed herein, an effect that it is possible to increase reliability in connection and transmission properties in interconnects in the wiring board is enabled.

(Note) A method of manufacturing a wiring board, the method comprising:
forming a core board by forming an interconnect layer on an upper surface and a lower surface of a substrate;
forming a first interconnect structure by layering an interconnect layer and an insulating layer on an upper surface of the core board;
forming a second interconnect structure by layering an interconnect layer and an insulating layer on a lower surface of the core board; and
forming a through-hole that penetrates to a pad contained in the interconnect layer of the core board in the insulating layer of the second interconnect structure and the substrate of the core board or forming a through-hole that penetrates to a pad contained in the interconnect layer of the first interconnect structure in the insulating layer of the second interconnect structure, the substrate of the core board, and the insulating layer of the first interconnect structure.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
a core board including an interconnect layer that is formed on an upper surface and a lower surface of a substrate;
a first interconnect structure that includes an interconnect layer and an insulating layer that are layered on an upper surface of the core board;
a second interconnect structure that includes an interconnect layer and an insulating layer that are layered on a lower surface of the core board; and
a through-hole that penetrates the insulating layer of the second interconnect structure and the substrate of the core board to a pad that is contained in the interconnect layer of the core board or that penetrates the insulating layer of the second interconnect structure, the substrate of the core board, and the insulating layer of the first interconnect structure to a pad that is contained in the interconnect layer of the first interconnect structure.

2. The wiring board according to claim 1, wherein the pad has a concave on a surface that is exposed to a bottom plane of the through-hole.

3. The wiring board according to claim 2, wherein the concave has a taper shape whose width decreases as it separates from the surface on which the pad is exposed.

4. The wiring board according to claim 1, wherein the second interconnect structure has another pad on an interconnect layer that is the lowest layer that is exposed to a surface of the second interconnect structure, and
the pad is a pad for signals that transmits a signal for which a transmission rate is higher than that for a signal that is transmitted to the another pad.

5. The wiring board according to claim 1, wherein the pad includes
a signal pad for signals; and
a ground pad for grounding that is arranged such that the ground pad surrounds an outer circumference of the signal pad.

6. A semiconductor device comprising:
a wiring board;
a semiconductor chip that is mounted on the wiring board; and
a mount board on which the wiring board with the semiconductor chip mounted thereon is mounted,
wherein the wiring board includes:
a core board including an interconnect layer that is formed on an upper surface and a lower surface of a substrate;
a first interconnect structure that includes an interconnect layer and an insulating layer that are layered on an upper surface of the core board;
a second interconnect structure that includes an interconnect layer and an insulating layer that are layered on a lower surface of the core board; and
a through-hole that penetrates the insulating layer of the second interconnect structure and the substrate of the core board to a pad that is contained in the interconnect layer of the core board or that penetrates the insulating layer of the second interconnect structure, the substrate of the core board, and the insulating layer of the first interconnect structure to a pad that is contained in the interconnect layer of the first interconnect structure,
the mount board includes
an electrode pad that is formed on an upper surface of the mount board;
an electrode pin that is connected to the electrode pad and that stands on the upper surface of the mount board, and
the electrode pin is inserted into the through-hole of the wiring board mounted on the mount board and makes contact with the pad that is exposed from the through-hole.

7. The semiconductor device according to claim 6, wherein the pad has a concave on a surface that is exposed to a bottom plane of the through-hole, and
the electrode pin is fitted into the concave of the pad.

8. The semiconductor device according to claim 6, wherein the pad includes
a signal pad for signals; and
a ground pad for grounding that is arranged around the signal pad,
the electrode pin includes
an internal conductor for signals; and
an external conductor that is arranged such that the external conductor surrounds an outer circumference of the internal conductor, and
frhtrrwith the electrode pin being inserted into the through-hole, the internal conductor makes contact with the signal pad and the external conductor makes contact with the ground pad.
